(19) United States
(12) Patent Application Publication
(10) Pub. No.: US 2005/0123288 A1
(43) Pub. Date: Jun. 9, 2005

(54) Gas injection head, method for manufacturing the same, semiconductor manufacturing device with the gas injection head and anti-corrosion product

(75) Inventors: Yasutaka Ito, Ibi-gun (JP); Jun Ohashi, Ibi-gun (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: IBIDEN CO., LTD., Ogaki-shi (JP)

(21) Appl. No.: 10/986,216

(22) Filed: Nov. 12, 2004

Related U.S. Application Data
(60) Provisional application No. 60/518,657, filed on Nov. 12, 2003.

(51) Int. Cl. F27B 5/14; F26B 3/30; H01L 21/324

(52) U.S. Cl. 392/418; 219/390; 438/795

(57) ABSTRACT

A gas injection head which is configured to jet a reactive gas includes a head surface. The gas injection head includes a nitride ceramic containing a rare earth compound which is present on the head surface.

### CROSS-REFERENCE TO RELATED APPLICATIONS

The present application claims priority under 35 U.S.C. §119(e) to U.S. Provisional Application No. 60/518,657, filed Nov. 12, 2003. The contents of the Provisional Application are incorporated herein by reference in their entirety.

### BACKGROUND OF THE INVENTION

1. Field of the Invention

The present invention relates to a gas injection head, a method for manufacturing the gas injection head, a semiconductor manufacturing device with the gas injection head and an anti-corrosion product.

2. Discussion of the Background

A known gas injection head jets out a gas having reactivity (reactive gas or process gas) into a plasma CVD device, as shown in Japanese Patent Laid-open Gazette No. 2002-231638. The contents of this application are incorporated herein by reference in their entirety. The reactive gas spouted into the plasma CVD device is decomposed and excited to plasma by glow discharge generated in the device and is accumulated as gas molecules on a substrate like a wafer located in the plasma CVD device. A thin film is thus formed on the substrate. This gas injection head is a ceramic porous body having an alumina content of not less than 99.0% by weight.

The gas injection head disclosed in Japanese Patent Laid-open Gazette No. 2002-231638 is mainly composed of alumina.

### SUMMARY OF THE INVENTION

According to one aspect of the present invention, a gas injection head which is configured to jet a reactive gas includes a head surface. The gas injection head includes a ceramic containing a rare earth compound which is present on the head surface.

According to another aspect of the present invention, a method for manufacturing a gas injection head configured to jet a reactive gas includes mixing rare earth oxide with a ceramic material to make a mixture which includes at least about 1% and at most about 10% by weight of the rare earth oxide. The mixture is molded to make a molded object. The molded object is heated at at least about 1800° C. and at most about 1900° C. for at least about 2 hours and at most about 10 hours.

According to yet another aspect of the present invention, a semiconductor manufacturing device includes a gas injection head configured to jet a reactive gas. The gas injection head includes a ceramic containing a rare earth compound which is present on the head surface of the head surface.

According to yet another aspect of the present invention, an anti-corrosion product includes a ceramic containing a rare earth compound which is present on a surface of the product.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 schematically illustrates the structure of a plasma CVD device 10;

FIGS. 2(a), 2(b), and 2(c) are a front view, a vertical sectional view, and a bottom view of a shower-type gas injection head 18;

FIGS. 3(a) and 3(b) are a front view and a vertical sectional view of a nozzle-type gas injection head 22;

FIG. 4 is a table showing results of examples;

FIG. 5 is an SEM photo of head surface; and

FIG. 6 is a schematic illustration of a CVD device.

### DESCRIPTION OF THE EMBODIMENTS

The embodiments will now be described with reference to the accompanying drawings, wherein like reference numerals designate corresponding or identical elements throughout the various drawings.

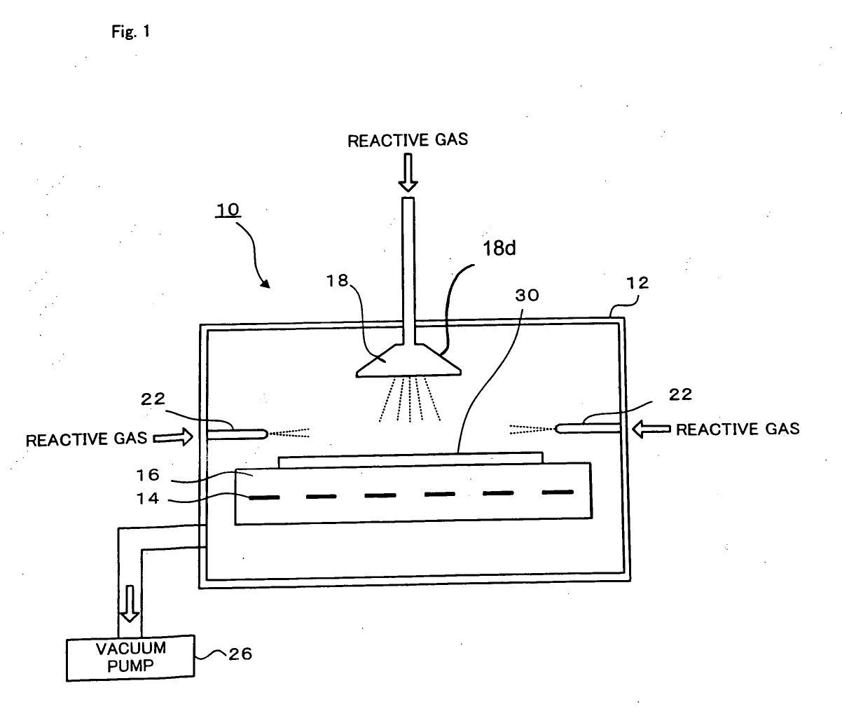

One embodiment according to the invention is discussed below with reference to the accompanied drawings. FIG. 1 schematically illustrates the structure of a plasma CVD device 10. The plasma CVD device 10 has a disc-shaped substrate holder 16, a shower-type gas injection head 18, and nozzle-type gas injection heads 22, which are located in a cylindrical vacuum chamber 12 having circular top face and bottom face, as shown in FIG. 1. A processing object 30, such as a silicon wafer, is placed on the disc-shaped substrate holder 16 and is heated by built-in heaters 14. The shower-type gas injection head 18 is located on the ceiling face of the vacuum chamber 12 to spout a gas having reactivity (reactive gas) into the vacuum chamber 12. The nozzle-type gas injection heads 22 are located on the inner circumferential face of the vacuum chamber 12 to spout the same reactive gas into the vacuum chamber 12. The shower-type gas injection head 18 is located on the approximate center of the ceiling face of the vacuum chamber 12. A number of the nozzle-type gas injection heads 22 are located along the inner circumferential face of the vacuum chamber 12. The vacuum chamber 12 is evacuated with a vacuum pump 26 and has a pair of electrodes (not shown), between which a high-frequency voltage is applied, therein.

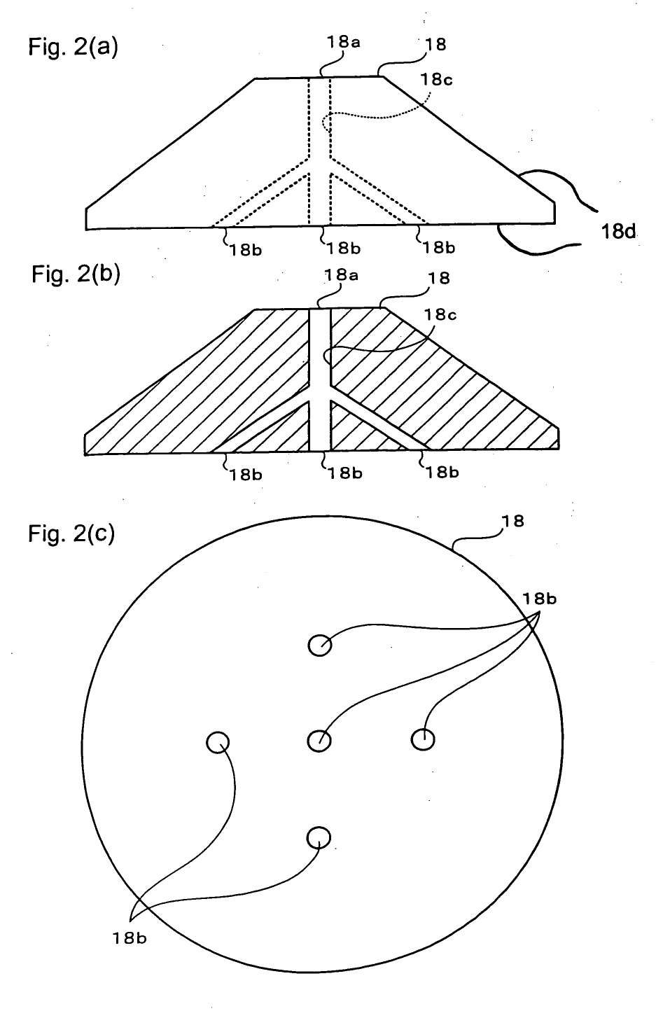

The shower-type gas injection head 18 is described with reference to FIGS. 2(a), 2(b), and 2(c). FIGS. 2(a), 2(b), and 2(c) are a front view, a vertical sectional view, and a bottom view of the shower-type gas injection head 18. The shower-type gas injection head 18 is formed in a roughly truncated corn shape and has one reactive gas inlet 18a on the center of its top face and five reactive gas outlets 18b on the center of its bottom face and at positions of equal distances from the center. A gas conduit 18c is formed in the shower-type gas injection head 18 to run from the reactive gas inlet 18a and to be branched off to the multiple reactive gas outlets 18b. The shower-type gas injection head 18 is a ceramic body that is mainly composed of aluminum nitride as the primary component and contains an yttrium compound, where the yttrium compound is present on the head surface 18d. The yttrium compound content in the ceramic body decreases from the head surface 18d toward the inside of the ceramic body. Even though the outermost yttrium compound comes off, the yttrium compound on the next layer functions to prevent corrosion of the ceramic. The shower-type gas injection head 18 has the Y percentage preferably in a range of 30 to 85% or more preferably in a range of 60 to 85%. The yttrium compound preferably covers over part of the grain boundary of aluminum nitride on the head surface 18d.

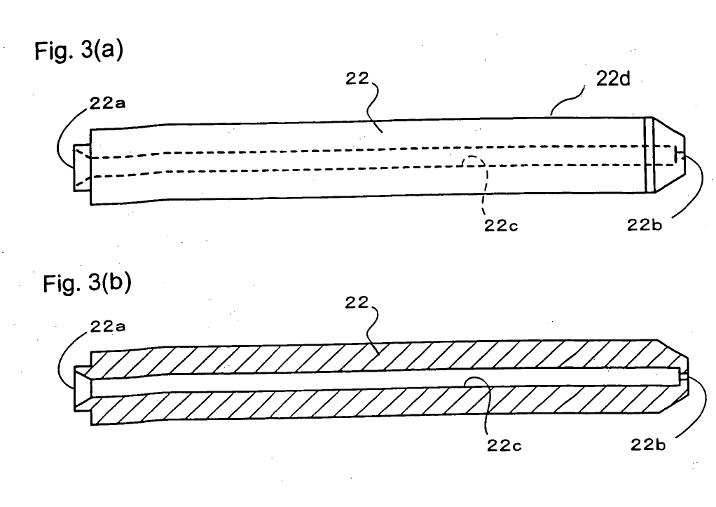

The nozzle-type gas injection head 22 is described with reference to FIG. 3. FIGS. 3(a) and 3(b) are a front view and a vertical sectional view of the nozzle-type gas injection head 22. The nozzle-type gas injection head 22 is formed in a substantially cylindrical shape and has one reactive gas inlet 22a on the center of its base end face and one reactive gas outlet 22b on the center of its free end. A gas conduit 22c is formed in the nozzle-type gas injection head 22 to run straight from the reactive gas inlet 22a to the reactive gas outlet 22b without any branching. Like the shower-type gas injection head 18, the nozzle-type gas injection head 22 is a ceramic body that is mainly composed of aluminum nitride as the primary component and contains the yttrium compound, where the yttrium compound is present on the head surface 22d.

The operation of the plasma CVD device 10 of the embodiment, that is, the process of forming a film on the surface of the processing object like a silicon wafer, is described briefly. A non-processed processing object 30 is conveyed by a non-illustrated conveyor into the vacuum chamber 12 and is located on the top of the substrate holder 16. The vacuum chamber 12 is evacuated to a preset degree of vacuum with the vacuum pump 16, and the processing object 30 is heated by the built-in heaters 14 of the substrate holder 16. A reactive gas is introduced at preset flow rates into the reactive gas inlet 18a of the shower-type gas injection head 18 and into the reactive gas inlets 22a of the respective nozzle-type gas injection heads 22 by a non-illustrated mass flow controller, and a high-frequency voltage is applied between the pair of electrodes (not shown). The reactive gas spouted from the respective reactive gas outlets 18b of the shower-type gas injection head 18 and from the reactive gas outlets 22b of the respective nozzle-type gas injection heads 22 into the vacuum chamber 12 is decomposed and excited to plasma by glow discharge generated between the pair of electrodes. The plasma gas molecules are then accumulated on the surface of the processing object 30 to form a thin film.

In the structure of the embodiment discussed above, even when the shower-type gas injection head 18 and the nozzle-type gas injection heads 22 are exposed to a plasma atmosphere for a long time period, the presence of the yttrium compound on the head surface effectively prevents generation of particles, compared with the conventional alumina gas injection head. The Y percentage of at least about 30% (especially of at least about 60%) reduces generation of particles, while the Y percentage of at most about 85% relieves the adverse effects of the difference in thermal expansion between the yttrium compound and aluminum nitride. Coverage of the yttrium compound over part of the grain boundary of aluminum nitride on the head surface effectively prevents penetration of the reactive gas into the grain boundary of aluminum nitride and thereby generation of particles. The holes corresponding to the gas conduits 18c and 22c are formed in the respective gas injection heads 18 and 22, prior to heating. The yttrium compound is thus present on the surface of the inner wall of the gas conduits 18c and 22c. This effectively reduces generation of particles in the gas conduits 18c and 22c.

According to the embodiment of the present invention, a gas injection head hardly produces particles even when being exposed to a corrosive gas atmosphere or a plasma atmosphere for a long time period.

The gas injection head according to the embodiment of the present invention includes a ceramic containing a rare earth compound, and the rare earth compound is present on a head surface. The function of the rare earth compound present on the head surface effectively reduces an amount of particles to be generated even when the gas injection head is exposed to a corrosive gas atmosphere or a plasma atmosphere for a long time period.

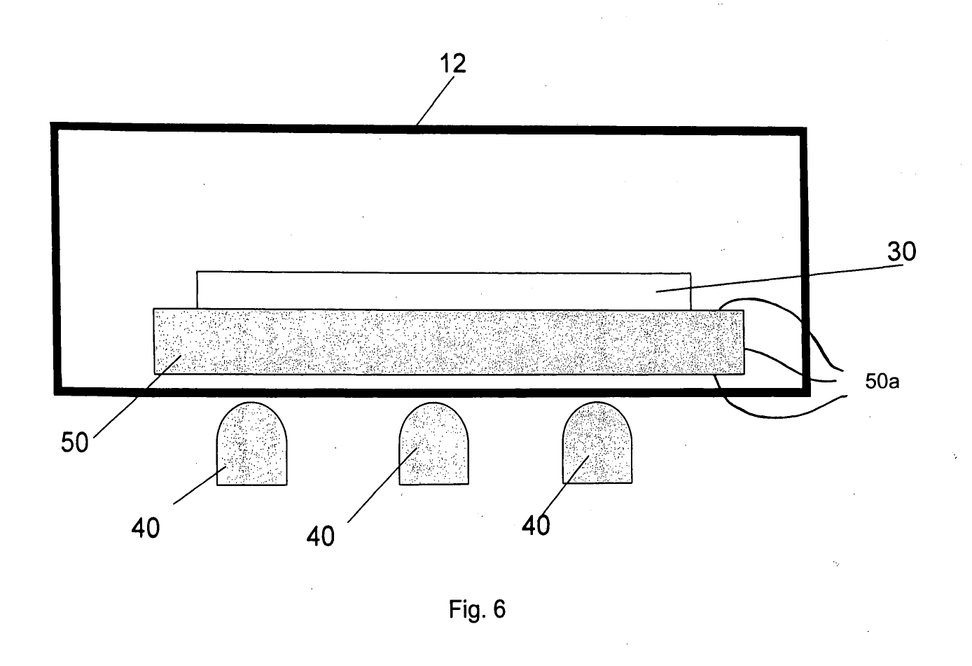

FIG. 6 shows a CVD device. Referring to FIG. 6, the CVD device includes a chamber 12, an anti-corrosion product 50 which is provided in the chamber 12, and infrared ray lamps 40 provided outside the chamber 12. The inner space of the chamber 12 is adjusted as high vacuum condition. Plasma gas is generated in the inner space of the chamber 12, if necessary. The anti-corrosion product 50 is, for example, a mount on which a silicon wafer 30 is to be placed. The anti-corrosion product 50 according to the embodiment of the present invention includes a ceramic which contains a rare earth compound which is present on a surface (50a) of the product 50. According to the embodiment of the present invention, the anti-corrosion product 50 hardly produces particles even when being exposed to a corrosive gas atmosphere or a plasma atmosphere for a long time period. It is preferable that the rare earth compound is scattered on the surface (50a) of the product 50. Although the rare earth compound has low thermal conductivity, the thermal conductivity of the anti-corrosion product 50 is higher than that of the rare earth compound because the rare earth compound is scattered on the surface (50a) of the product 50, but does not fully cover the surface (50a). Therefore, the anti-corrosion product 50 has not only an anti-corrosion property but also thermal conductivity higher than that of the rare earth compound. The anti-corrosion product 50 according to the embodiment of the present invention has a structure in which grain boundary of the ceramic on the surface is covered with the rare earth compound. This structure has homogenous dispersion of rare earth compound.

The anti-corrosion product according to the embodiment of the present invention may be used as, for example, a gas injection head, a mount, a chamber, an electrode, a heater.

The ceramic used for the embodiment of the present invention is not limited. For example, carbide ceramic, oxide ceramic, or nitride ceramic may be used.

The carbide ceramic is not limited, but may be, for example, silicon carbide, titanium carbide, or boron carbide.

The oxide ceramic is not limited, but may be, for example, silicon oxide, or aluminum oxide.

The nitride ceramic is not specifically limited, but may be, for example, silicon nitride, aluminum nitride, boron nitride, or sialon. Aluminum nitride is preferable. The rare earth compound is, for example, a lanthanoid compound, a scandium compound, or an yttrium compound. An yttrium compound is preferable. The yttrium compound is not specifically limited, but may be, for example, yttrium nitride, yttrium carbide, or an yttrium compound produced when yttria and the nitride ceramic are heated.

In the gas injection head according to the embodiment of the present invention, the head surface is not smoothed (for example, by grinding or polishing). The rate of the rare earth compound on the head surface calculated according to an SEM image is desirably at least about 30%. This arrangement effectively reduces generation of particles, compared with the gas injection head that is composed of the rare earth compound-containing nitride ceramic but has the smoothed head surface or with the gas injection head having the rate of the rare earth compound on the head surface of less than 30%. The rate of the rare earth compound on the head surface of at least about 60% enhances the effects of reducing generation of particles. The rate of the rare earth compound of greater than 85% may, however, have adverse effects, for example, to cause cracks due to a difference in thermal expansion between the rare earth compound and the nitride ceramic.

In the gas injection head according to the embodiment of the present invention, it is preferable that at least part of grain boundary of the nitride ceramic on the head surface is covered with the rare earth compound. This further enhances the effects of reducing generation of particles. In an expected mechanism of generation of particles, the reactive gas (the plasma gas in the case of plasma CVD) penetrates into the grain boundary of the nitride ceramic to corrode the nitride ceramic and make particles fall off the nitride ceramic. The presence of the rare earth compound having high corrosion resistance in the grain boundary of the nitride ceramic effectively prevents penetration of the reactive gas and thereby generation of the particles.

In the gas injection head according to the embodiment of the present invention, it is preferable that the head surface includes an inner wall surface of a gas spout hole for spouting the reactive gas. This structure reduces generation of particles from the inner wall surface of the gas spout hole. Here the gas spout hole may be formed to run from one reactive gas inlet to one reactive gas outlet without any branching or to run from one reactive gas inlet and to be branched off to multiple reactive gas outlets.

The method according to the embodiment of the present invention includes mixing 1 to 10% by weight of rare earth oxide (for example, yttria) with a nitride ceramic material to a mixture, molding the mixture to a molded object of a predetermined head shape, and heating the molded object at at least about 1800° C. and at most about 1900° C. for at least about 2 hours and at most about 10 hours to manufacture the gas injection head. A rare earth compound floats up and enters the grain boundary of the nitride ceramic on the head surface in the heating step. Accordingly, the yttrium compound content in the ceramic body decreases from the head surface 18d toward the inside of the ceramic body. The resulting gas injection head is accordingly composed of the nitride ceramic containing the rare earth compound, where the rare earth compound is present on the head surface.

The content of rare earth oxide of less than 1% by weight may cause the resulting gas injection head to have insufficient effects of reducing generation of particles. The content of rare earth of greater than 10% by weight, on the other hand, increases the rate of the rare earth compound on the head surface of the resulting gas injection head and may have the difference in thermal expansion between the rare earth compound and the nitride ceramic. The heating temperature of lower than 1800° C. may interfere with floating-up of a sufficient quantity of the rare earth compound to the surface. The heating temperature of higher than 1900° C., on the other hand, may cause the rare earth compound to cover over most of the surface and may cause cracks due to the difference in thermal expansion between the rare earth compound and the nitride ceramic. The heating time is determined appropriately according to the composition of the nitride ceramic material and the heating temperature and is, for example, 1 to 15 hours.

Smoothing the head surface after heating may lower the rate of the rare earth compound on the head surface to be less than 30%. It is accordingly preferable not to smooth the head surface after heating. Even when the head surface is smoothed after heating, however, subsequent heat treatment (annealing) generally causes the rare earth compound to float up to the head surface and recovers the rate of the rare earth compound on the head surface to be equal to or greater than 30%. Heat treatment is thus desirable after surface smoothing. Chemical etching after heating decreases the rate of the rare earth compound on the head surface. It is accordingly preferable not to chemically etch the head surface after heating. The percentage decrease in rate of the rare earth compound on the head surface by chemical etching is smaller than that by surface smoothing. Although, in order to control the particle generation, it is desirable to avoid surface smoothing or chemical etching after heating, the present invention does not exclude to perform surface smoothing or chemical etching after heating. When surface smoothing or chemical etching is required by some reason, however, surface smoothing or chemical etching may be performed.

In the gas injection head manufacturing method according to the embodiment of the present invention, an additive may be added according to the requirements in the step of mixing 1 to 10% by weight of rare earth oxide with the nitride ceramic material. Binders, solvents, and auxiliary sintering agents are typical examples of the additive. The binder is not specifically limited but may be, for example, one or plural selected among acrylic binders, ethyl cellulose, butyl cellosolve, and polyvinyl alcohol. The solvent is not specifically limited but may be, for example, one or plural selected among alcohols of 1 to 6 carbon atoms like methanol, ethanol, propanol, butanol, pentanol, and hexanol, α-terpineol, and glycol. The auxiliary sintering agent is not specifically limited but is, for example, CaO, Na2O, Li2O, or Rb2O3.

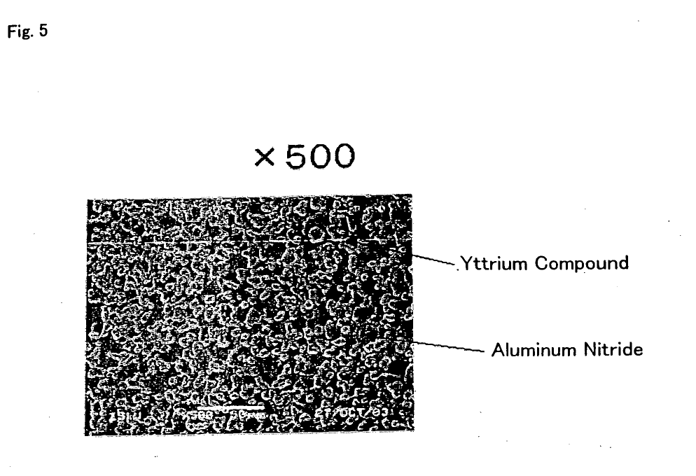

One example of the head surface of the gas injection head according to the embodiment of the present invention is described with reference to FIG. 5. FIG. 5 is an SEM photo of head surface of a gas injection head taken at a magnifying power of 2000. A rare earth compound used in this example is an yttrium compound. In the SEM photo of FIG. 5, the lighter color portion (whiter portion) represents the presence of the yttrium compound, and the darker color portion represents the nitride ceramic (nitride aluminum in this example). This photo shows that the yttrium compound is present to cover the grain boundary of aluminum nitride on the head surface. The yttrium compound is scattered among grains of aluminum nitride on the head surface. The lighter color portion was qualitatively analyzed with an energy dispersive X-ray spectroscopic analyzer (EDS, combination of a scanning electron microscope S4300 by Hitachi Ltd. with a detector by EDAX Japan KK was used in this embodiment). The qualitative analysis gave peaks of C, N, O, Al, and Y. The peak of Al is naturally ascribed to the primary component, aluminum nitride. The yttrium compound in the lighter color portion is thus expected to be yttrium nitride, carbide, and oxide.

The rate of the rare earth compound on the head surface is calculated according to an SEM (scanning electron microscope) photo. The concrete procedure of calculation is described. The nitride ceramic and the yttrium compound as rare earth compound generally appear in the darker color and in the lighter color in the SEM photo as shown in FIG. 5. The procedure draws vertical and horizontal lines on an area of 300 μm×300 μm in actual dimensions in an SEM photo at a magnifying power of 500 and divides the area into lattices of 5 μm×5 μm in actual dimensions. The procedure then examines the shading of respective lattice points, calculates a ratio of lighter color lattice points to all lattice points, and sets the calculated ratio to the ‘rate of the rare earth compound on the head surface’ (Y percentage). This series of operation may be repeated multiple times (for example, 10 times), and the average may be set to the “rate of the rare earth compound on the head surface.”

### EXAMPLES

Examples of the nozzle-type gas injection head 22 in the above embodiment are described below.

### Example 1

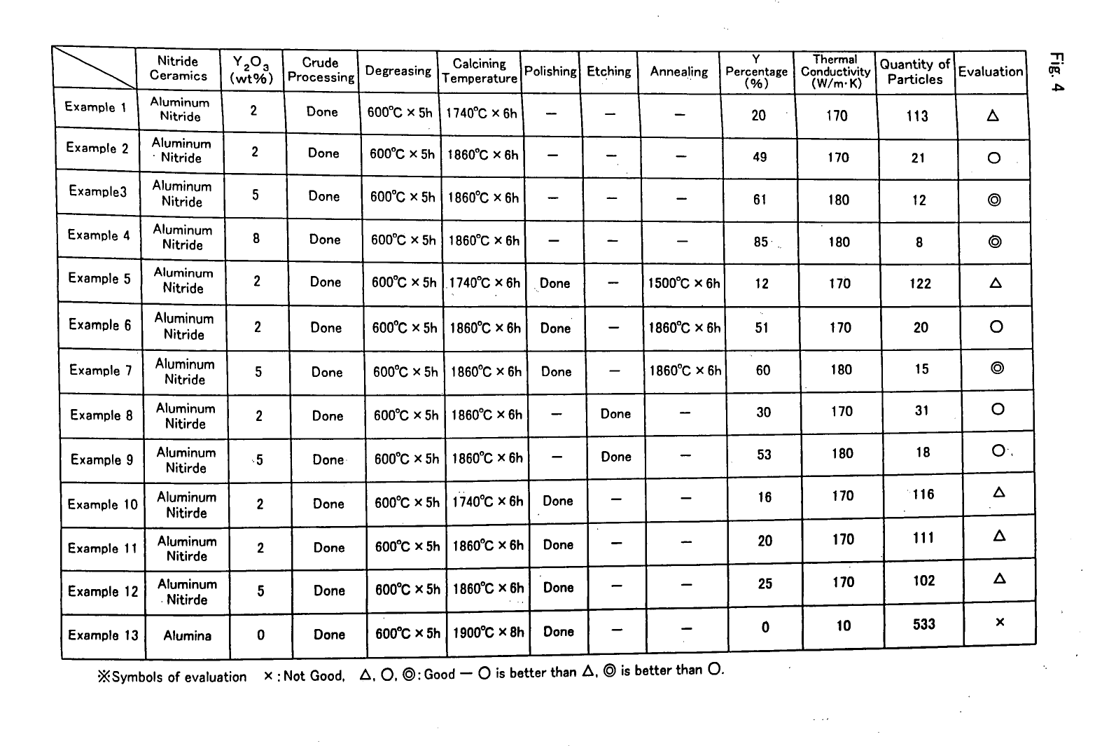

The procedure first mixed 98 parts by weight of aluminum nitride powder (manufactured by Tokuyama Corp., average particle diameter: 1.1 μm), 2 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1740° C. for 6 hours. This gave the nozzle-type gas injection head 22 without any surface smoothing by polishing or grinding and without any chemical etching. The Y percentage of the resulting nozzle-type gas injection head 22 was calculated by the method discussed above. Here the Y percentage is the average of 10 SEM photos. After a 1000-hour plasma endurance test, a wafer of 300 mm in diameter was located in a vacuum chamber, and a thin film was formed on the surface of the wafer by plasma CVD. After the film formation, the quantity of particles accumulated on the wafer was measured. The reactive gas used here was monosilane (SiH4) or tetraethoxysilane (SiOEt)4) to generate silane plasma. The results of the experiments are shown in the table of FIG. 4.

### Example 2

The procedure first mixed 98 parts by weight of aluminum nitride powder (manufactured by Tokuyama Corp., average particle diameter: 1.1 μm), 2 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1860° C. for 6 hours. This gave the nozzle-type gas injection head 22 without any surface smoothing by polishing or grinding and without any chemical etching. The Y percentage and the quantity of particles were measured with regard to the resulting nozzle-type gas injection head 22, like Example 1. The results of the experiments are shown in the table of FIG. 4.

### Example 3

The procedure first mixed 95 parts by weight of aluminum nitride powder (manufactured by Tokuyama Corp., average particle diameter: 1.1 μm), 5 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1860° C. for 6 hours. This gave the nozzle-type gas injection head 22 without any surface smoothing by polishing or grinding and without any chemical etching. The Y percentage and the quantity of particles were measured with regard to the resulting nozzle-type gas injection head 22, like Example 1. The results of the experiments are shown in the table of FIG. 4.

### Example 4

The procedure first mixed 92 parts by weight of aluminum nitride powder (manufactured by Tokuyama Corp., average particle diameter: 1.1 μm), 8 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1860° C. for 6 hours. This gave the nozzle-type gas injection head 22 without any surface smoothing by polishing or grinding and without any chemical etching. The Y percentage and the quantity of particles were measured with regard to the resulting nozzle-type gas injection head 22, like Example 1. The results of the experiments are shown in the table of FIG. 4.

### Example 5

The procedure first mixed 98 parts by weight of aluminum nitride powder (manufactured by Tokuyama Corp., average particle diameter: 1.1 μm), 2 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1740° C. for 6 hours. The surface of the heated object was smoothed by grinding and polishing and was subsequently annealed in a nitrogen atmosphere at 1500° C. for 6 hours. This gave the nozzle-type gas injection head 22. The Y percentage and the quantity of particles were measured with regard to the resulting nozzle-type gas injection head 22, like Example 1. The results of the experiments are shown in the table of FIG. 4.

### Example 6

The procedure first mixed 98 parts by weight of aluminum nitride powder (manufactured by Tokuyama Corp., average particle diameter: 1.1 μm), 2 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1860° C. for 6 hours. The surface of the heated object was smoothed by grinding and polishing and was subsequently annealed in a nitrogen atmosphere at 1860° C. for 6 hours. This gave the nozzle-type gas injection head 22. The Y percentage and the quantity of particles were measured with regard to the resulting nozzle-type gas injection head 22, like Example 1. The results of the experiments are shown in the table of FIG. 4.

### Example 7

The procedure first mixed 95 parts by weight of aluminum nitride powder (manufactured by Tokuyama Corp., average particle diameter: 1.1 μm), 5 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1860° C. for 6 hours. The surface of the heated object was smoothed by grinding and polishing and was subsequently annealed in a nitrogen atmosphere at 1860° C. for 6 hours. This gave the nozzle-type gas injection head 22. The Y percentage and the quantity of particles were measured with regard to the resulting nozzle-type gas injection head 22, like Example 1. The results of the experiments are shown in the table of FIG. 4.

### Example 8

The procedure first mixed 98 parts by weight of aluminum nitride powder (manufactured by Tokuyama Corp., average particle diameter: 1.1 μm), 2 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1860° C. for 6 hours. The surface of the heated object was soaked in a 10% NaOH solution at 60° C. for 30 seconds for chemical etching. This gave the nozzle-type gas injection head 22. The Y percentage and the quantity of particles were measured with regard to the resulting nozzle-type gas injection head 22, like Example 1. The results of the experiments are shown in the table of FIG. 4.

### Example 9

The procedure first mixed 95 parts by weight of aluminum nitride powder (manufactured by Tokuyama Corp., average particle diameter: 1.1 μm), 5 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1860° C. for 6 hours. The surface of the heated object was soaked in a 10% NaOH solution at 60° C. for 30 seconds for chemical etching. This gave the nozzle-type gas injection head 22. The Y percentage and the quantity of particles were measured with regard to the resulting nozzle-type gas injection head 22, like Example 1. The results of the experiments are shown in the table of FIG. 4.

### Example 10

The procedure first mixed 98 parts by weight of aluminum nitride powder (manufactured by Tokuyama Corp., average particle diameter: 1.1 μm), 2 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1740° C. for 6 hours. The surface of the heated object was smoothed by grinding and polishing. This gave the nozzle-type gas injection head 22. The Y percentage and the quantity of particles were measured with regard to the resulting nozzle-type gas injection head 22, like Example 1. The results of the experiments are shown in the table of FIG. 4.

### Example 11

The procedure first mixed 98 parts by weight of aluminum nitride powder (manufactured by Tokuyama Corp., average particle diameter: 1.1 μm), 2 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1860° C. for 6 hours. The surface of the heated object was smoothed by grinding and polishing. This gave the nozzle-type gas injection head 22. The Y percentage and the quantity of particles were measured with regard to the resulting nozzle-type gas injection head 22, like Example 1. The results of the experiments are shown in the table of FIG. 4.

### Example 12

The procedure first mixed 95 parts by weight of aluminum nitride powder (manufactured by Tokuyama Corp., average particle diameter: 1.1 μm), 5 parts by weight of yttrium oxide (Y2O3: yttria, average particle diameter: 0.4 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1860° C. for 6 hours. The surface of the heated object was smoothed by grinding and polishing. This gave the nozzle-type gas injection head 22. The Y percentage and the quantity of particles were measured with regard to the resulting nozzle-type gas injection head 22, like Example 1. The results of the experiments are shown in the table of FIG. 4.

### Example 13

The procedure first mixed 100 parts by weight of aluminum nitride powder (average particle diameter: 2.3 μm), 4 parts by weight of an acrylic binder, and 53 parts by weight of an alcohol mixture of 1-butanol and ethanol and granulated the mixture. The procedure then molded the granules to a substantially cylindrical shape by SIP forming and formed a hole corresponding to the gas conduit 22c to give a molded object of a desired shape (crude processing). The molded object was degreased in an oxidizing atmosphere at 600° C. for 5 hours and was heated in the flow of nitrogen gas at 1900° C. for 8 hours. The surface of the heated object was smoothed by grinding and polishing. This gave the nozzle-type gas injection head 22. The Y percentage and the quantity of particles were measured with regard to the resulting nozzle-type gas injection head 22, like Example 1. The results of the experiments are shown in the table of FIG. 4.

### Example 14

The method for manufacturing an anti-corrosion product, for example, the mount 50 shown in FIG. 6, is explained. First, 95 parts by weight of silicon carbide powder (an average particle diameter: 1.1 μm), 5 parts by weight of yttrium oxide (Y2O3: yttria, an average particle diameter: 0.4 μm), 4 parts by weight of an acrylic binder, and 53 parts by weight of an alcohol mixture of 1-butanol and ethanol are mixed and the mixture is granulated. Then, the granules are molded to have a disk shape. The molded object is degreased in an oxidizing atmosphere at about 600° C. for about 5 hours and is heated in the flow of nitrogen gas at about 2000° C. for about 6 hours. This disk shaped sintered body is used as a mount.

### Results of Experiments

As clearly shown in the table of FIG. 4, all the ceramic gas injection heads of Examples 1 to 12, which were mainly composed of aluminum nitride as the primary component and contained the yttrium compound, had the limited quantity of particles after the 1000-hour plasma duration test, compared with the gas injection head of alumina ceramic in Example 13. SEM photos of the head surfaces of the respective gas injection heads in Examples 1 to 12 were taken. As shown in FIG. 5, at least part of the grain boundary of aluminum nitride was covered with the yttrium compound. The gas injection heads of Examples 1 to 12 were evaluated in the order of the less quantity of particles. The order was those having the Y percentage of not less than 60% (Examples 3, 4, 7), those having the Y percentage of not less than 30% but less than 60% (Examples 2, 6, 8, and 9), and those having the Y percentage of less than 30% (Examples 1, 5, 10-12). The smoothed gas injection heads after heating had greater quantities of particles than the non-smoothed gas injection heads after heating (comparison between Examples 2, 3 and Examples 11, 12). The smoothed and annealed gas injection heads after heating had less quantities of particles than the smoothed but non-annealed gas injection heads after heating (comparison between Example 6, 7 and Examples 11, 12). The chemically-etched gas injection heads after heating had no significant deterioration with regard to both the Y percentage and the quantity of particles, compared with the non-chemically-etched gas injection heads after heating (comparison between Examples 2, 3 and Examples 8, 9). The gas injection head heated at a temperature of lower than 1800° C. had significant deterioration with regard to both the Y percentage and the quantity of particles, compared with the gas injection head heated at a temperature of 1800 to 1900° C. (comparison between Example 1 and Example 2). The increase in percent by weight of yttria tended to increase the Y percentage and decrease the quantity of particles (Examples 2 to 4).

Obviously, numerous modifications and variations of the present invention are possible in light of the above teachings. It is therefore to be understood that within the scope of the appended claims, the invention may be practiced otherwise than as specifically described herein.

1. A gas injection head configured to jet a reactive gas, comprising:
a head surface; and
a ceramic including a rare earth compound which is present on the head surface.

2. A gas injection head in accordance with claim 1, wherein the ceramic is a nitride ceramic.

3. A gas injection head in accordance with claim 1, wherein the rare earth compound is an yttrium compound.

4. A gas injection head in accordance with claim 1, wherein the head surface is not smoothed, and a rate of the rare earth compound on the head surface calculated according to an SEM image at least about 30%.

5. A gas injection head in accordance with claim 1, wherein the rare earth compound is scattered on the surface.

6. A gas injection head in accordance with claim 1, wherein at least part of grain boundary of the ceramic on the head surface is covered with the rare earth compound.

7. A gas injection head in accordance with claim 1, wherein the ceramic is made of aluminum nitride.

8. A gas injection head in accordance with claim 1, wherein a rate of the rare earth compound on the head surface calculated according to an SEM image is at least about 60%.

9. A gas injection head in accordance with claim 1, wherein a rate of the rare earth compound on the head surface calculated according to an SEM image is at most about 85%.

10. A gas injection head in accordance with claim 1, wherein the head surface includes an inner wall surface of a gas spout hole for spouting the reactive gas.

11. A method for manufacturing a gas injection head configured to jet a reactive gas, comprising:
mixing rare earth oxide with a ceramic material to make a mixture which includes at least about 1% and at most about 10% by weight of the rare earth oxide;
molding the mixture to make a molded object; and
heating the molded object at at least about 1800° C. and at most about 1900° C. for at least about 2 hours and at most about 10 hours.

12. A manufacturing method in accordance with claim 11, wherein the rare earth oxide is yttria.

13. A manufacturing method in accordance with claim 11, said method completing the gas injection head without smoothing a head surface, after heating.

14. A semiconductor manufacturing device comprising:
a gas injection head configured to jet a reactive gas and comprising:
a head surface; and
a ceramic including a rare earth compound which is present on the head surface.

15. An anti-corrosion product comprising:
a ceramic including a rare earth compound which is present on a surface of the product.

16. An anti-corrosion product in accordance with claim 15, wherein the ceramic is a nitride ceramic.

17. An anti-corrosion product in accordance with claim 15, wherein the rare earth compound is an yttrium compound.

18. An anti-corrosion product in accordance with claim 15, wherein the rare earth compound is scattered on the surface.

19. An anti-corrosion product in accordance with claim 15, wherein at least part of grain boundary of the ceramic on the surface is covered with the rare earth compound.

20. A gas injection head in accordance with claim 1, wherein a rare earth compound content in the ceramic decreases from the head surface toward an inside of the gas injection head.

21. An anti-corrosion product in accordance with claim 15, wherein a rare earth compound content in the ceramic decreases from the surface toward an inside of the anti-corrosion product.
